(19) United States
(12) Patent Application Publication
(10) Pub. No.: US 2023/0356342 A1
(43) Pub. Date: Nov. 9, 2023

(54) ELECTROSTATIC CHUCK

(71) Applicant: MiCo Ceramics Ltd., Gyeonggi-do (KR)

(72) Inventors: Sang Bum CHO, Gyeonggi-do (KR); Jung Hyun PARK, Gyeonggi-do (KR); Jun Sung LEE, Gyeonggi-do (KR)

(21) Appl. No.: 18/140,862

(22) Filed: Apr. 28, 2023

(30) Foreign Application Priority Data
May 9, 2022 (KR) 10-2022-0056603

(51) Int. Cl. B23Q 11/10; H02N 13/00; B23Q 3/15

(52) U.S. Cl. CPC B23Q 11/10; H02N 13/00; B23Q 3/15

(57) ABSTRACT

The present disclosure relates to an electrostatic chuck having an efficient cooling structure. The present disclosure provides an electrostatic chuck including a base substrate including a cooling water channel, and a plate configured to support a wafer on the base substrate and including a plate comprising a cooling gas hole configured to supply a cooling gas to the wafer. The base substrate includes a cooling water inlet and a cooling gas inlet in a center thereof, the plate is in communication with the cooling gas inlet of the base substrate and include a cooling gas hole configured to spray a cooling gas to the wafer, and the electrostatic chuck further includes a shaft abutting the base substrate along a circumference of a central portion of the base substrate including the cooling water inlet and the cooling gas inlet.

### CROSS-REFERENCE TO RELATED APPLICATION

This application is based on and claims priority under 35 U.S.C. 119 to Korean Patent Application No. 10-2022-0056603, filed on May 9, 2022, in the Korean Intellectual Property Office, the disclosure of which is herein incorporated by reference in its entirety.

### FIELD

The present disclosure relates to an electrostatic chuck, and more particularly to an electrostatic chuck having an efficient cooling structure.

### BACKGROUND

Semiconductor devices or display devices are manufactured by laminating and patterning multiple thin film layers including dielectric layers and metal layers on a glass substrate, a flexible substrate, or a semiconductor wafer substrate through semiconductor processes such as a chemical vapor deposition (CVD) process, a physical vapor deposition (PVD) process, an ion implantation process, and an etch process. A chamber apparatus for performing these semiconductor processes is provided with an electrostatic chuck (ESC) configured to support various substrates, such as a glass substrate, a flexible substrate, and a semiconductor wafer substrate, and to fix a corresponding substrate, in particular, by using an electrostatic force.

Typically, an electrostatic chuck includes a base substrate and an electrostatic chuck plate (or an electrostatic chuck structure) disposed on the base substrate. Here, the electrostatic chuck plate is a multilayer structure that performs an electrostatic chuck function, and may include an insulating layer, an electrode layer on the insulating layer, and a dielectric layer on the electrode layer. In addition, the electrostatic chuck has a cooling structure configured to uniformly cool a substrate inside a chamber by using an external cooling gas (e.g., helium (He) gas).

FIG. 1 is a cross-sectional view schematically illustrating a structure of a conventional electrostatic chuck.

Referring to FIG. 1, the electrostatic chuck includes an electrostatic chuck plate 10 and a base substrate 30.

The base substrate 30 is provided with a cooling gas channel 34 configured to introduce a cooling gas from the outside. The cooling gas channel extends to the electrostatic chuck plate 10, and the cooling gas flowing through the cooling gas channel is sprayed to the surface of the electrostatic chuck plate to cool a wafer W. Multiple cooling gas holes may be provided in the surface of the electrostatic chuck plate. Meanwhile, the base substrate 30 is provided with a cooling path configured to circulate cooling water to cool the base substrate 30.

After performing a high-temperature process using the electrostatic chuck of FIG. 1, the high-temperature wafer requires rapid cooling for an etch process, a cleaning process, or a removal process. In addition, a silicon wafer on which a dielectric or metal thin film is deposited after a high-temperature process is exposed to a change in temperature during a process and is deformed. In general, a wafer cooled after a thin film process is deformed into a concave or convex shape. Therefore, it is difficult to rapidly cool a wafer only by using a cooling chuck due to the vacuum state in the chamber and deformation of the wafer.

### SUMMARY

Accordingly, the present disclosure has been made to solve the above problems and provides an electrostatic chuck having a cooling structure capable of rapid cooling.

In addition, the present disclosure provides an electrostatic chuck capable of intensively cooling a wafer on the top surface of the electrostatic chuck without heat loss to other structures around the body of the electrostatic chuck.

Furthermore, the present disclosure provides an electrostatic chuck capable of more smoothly controlling the temperature of a wafer.

In view of the foregoing, the present disclosure provides an electrostatic chuck including a base substrate including a cooling water channel, and a plate configured to support a wafer on the base substrate and including a cooling gas hole configured to supply a cooling gas to the wafer. The base substrate includes a cooling water inlet and a cooling gas inlet in a center thereof, the plate is in communication with the cooling gas inlet of the base substrate and includes the cooling gas hole configured to spray a cooling gas to the wafer, and the electrostatic chuck further includes a shaft abutting the base substrate along a circumference of a central portion of the base substrate including the cooling water inlet and the cooling gas inlet.

In the present disclosure, the shaft may include a connector assembly configured to introduce a fluid into the cooling water inlet and the cooling gas inlet.

In this case, the connector assembly may include a flange that is in contact with the base substrate and includes multiple through holes therein, and multiple pipes connected to the multiple through holes of the flange to introduce the fluid.

In the present disclosure, the flange may be in airtight contact with the base substrate.

In addition, the multiple through holes of the flange may communicate with the cooling water inlet or the cooling gas inlet of the base substrate. In this case, the flange may further include a ring-shaped groove for airtight sealing along the periphery of the through holes.

In the present disclosure, the plate may include a bipolar chuck electrode.

In addition, the plate may further include a built-in heater. The built-in heater may be a multi-zone heater having concentric 2 zones or 4 zones capable of actively controlling temperature from the edge area to the center of a wafer.

In the present disclosure, the plate may include a cooling flow path formed by a trench radially extending on a top surface thereof.

In addition, the cooling flow path of the plate may further include multiple cooling gas holes.

In the present disclosure, the plate may include an embossed pattern that comes into contact with the wafer.

In the present disclosure, the electrostatic chuck may further include a guide ring, and the guide ring may include a ring portion surrounding the side surface of the plate, and an extension portion extending from the ring portion to the top surface of the plate.

According to the present disclosure, it is possible to provide an electrostatic chuck having a cooling structure capable of rapid cooling.

In addition, the present disclosure is capable of providing an electrostatic chuck capable of intensively cooling a wafer on the top surface of the electrostatic chuck without heat loss to other structures around the body of the electrostatic chuck. Furthermore, the present disclosure is capable of providing an electrostatic chuck capable of more smoothly controlling the temperature of a wafer.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a cross-sectional view schematically illustrating a structure of a conventional electrostatic chuck.

FIG. 2 is a schematic cross-sectional view of an electrostatic chuck according to an embodiment of the present disclosure.

FIG. 3 is a view schematically illustrating a trench structure provided on the top surface of the plate as an embodiment of the present disclosure.

FIG. 4A is a front view of a connector assembly according to an embodiment of the present disclosure, and

FIG. 4B is a cross-sectional view of FIG. 4A.

FIG. 5 is a schematic cross-sectional view of an electrostatic chuck according to another embodiment of the present disclosure.

FIGS. 6A, 6B and 6C are views illustrating an example of application of a guide ring according to characteristics of a plate according to an embodiment of the present disclosure.

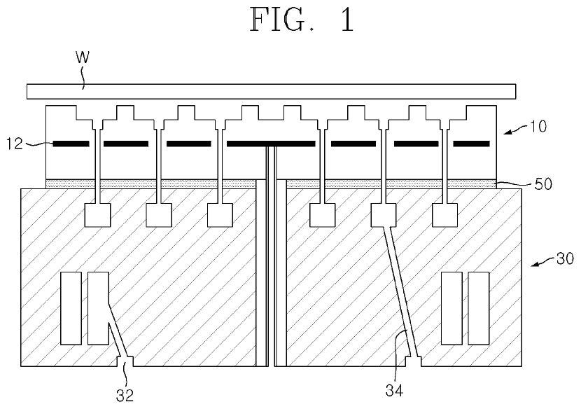

### DETAILED DESCRIPTION

Hereinafter, the present disclosure will be described in detail with reference to the accompanying drawings. Herein, like components in each drawing are denoted by like reference numerals if possible. In addition, detailed descriptions of already known functions and/or configurations will be omitted. In the following description, components necessary for understanding operations according to various embodiments will be mainly described, and descriptions of elements that may obscure the gist of the description will be omitted. In addition, some elements in the drawings may be exaggerated, omitted, or schematically illustrated. The size of each component does not entirely reflect the actual size, and therefore, the descriptions provided herein are not limited by the relative sizes or spacings of the components drawn in each drawing.

In describing the embodiments of the present disclosure, when it is determined that a detailed description of the known technology related to the present disclosure may unnecessarily obscure the subject matter of the present disclosure, the detailed description will be omitted. In addition, terms to be described later are defined in consideration of functions in the present disclosure and may vary according to the intention, custom, or the like of a user or operator. Therefore, the definitions of the terms should be made based on the description throughout this specification. Terms used in the detailed description are only for describing the embodiments of the present disclosure, and should not be treated as limiting. Unless expressly used otherwise, a singular form of expression includes meaning of a plural form. In this description, expressions such as “including” or “comprising” are intended to indicate any features, numbers, steps, operations, elements, or some or combinations thereof, and should not be construed to exclude the existence or possibility of one or more other features, numbers, steps, operations, elements, or some or combinations thereof.

In addition, terms such as “first” and “second” may be used to describe various components, but the components are not limited by the terms, and these terms are only used for the purpose of distinguishing one component from another.

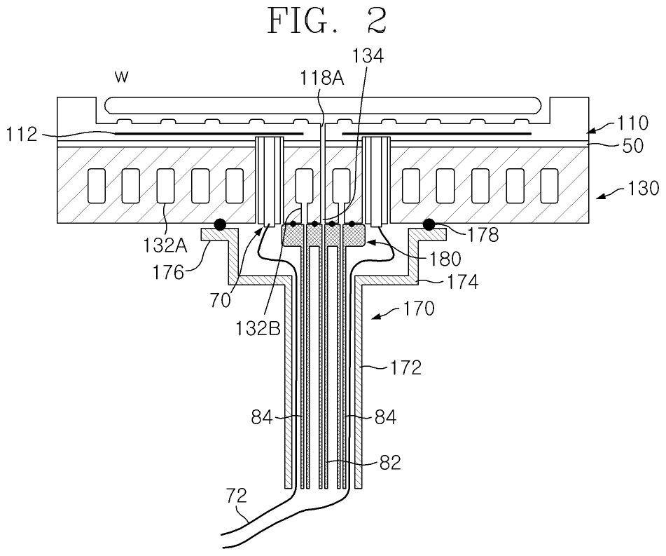

FIG. 2 is a schematic cross-sectional view of an electrostatic chuck according to an embodiment of the present disclosure.

Referring to FIG. 2, the electrostatic chuck according to an embodiment of the present disclosure includes a base substrate 130 and a plate 110. The illustrated electrostatic chuck may have a circular shape in a plan view. However, the present disclosure is not limited thereto, and in some cases, the electrostatic chuck may be designed to have other shapes such as an ellipse or a rectangle in a plan view.

In the present disclosure, the base substrate 130 is preferably a structure made of a metal having high thermal conductivity. For example, aluminum, an aluminum alloy, nickel, a nickel alloy, or stainless steel may be used as the base substrate, and the surface of the base substrate may be made of or coated with a material having resistance to plasma or a halogen-containing gas. For example, the surface of the base substrate may be made of anodized aluminum.

Meanwhile, in the present disclosure, the base substrate 130 may be made of a multi-layer structure including a plurality of metal layers. These metal layers may be bonded through a brazing process, a welding process, a bonding process, or the like.

A cooling water channel 132A is provided inside the base substrate 130. In order to introduce cooling water into the cooling water channel, a cooling water inlet 1326 is provided in the bottom surface of the base substrate 130. As illustrated, in the present disclosure, the cooling water inlet 132B is disposed in a central portion of the base substrate, that is, an area within a predetermined radius from the center of the base substrate. The cooling water introduced into the cooling water inlet 132B cools the base substrate while passing through the cooling water channel 132A and is then discharged.

A plate 110 is provided above the base substrate 130. The plate may be implemented by a dielectric material. The plate may include at least one material selected from a group consisting of aluminum oxide (Al₂O₃), aluminum nitride (AlN), silicon carbide (SiC), and silicon nitride (Si₃N₄). In addition, the plate 110 may include a thermal spray coating.

In the present disclosure, the plate 110 may be fixed on the base substrate 130 in an arbitrary manner. For example, the base substrate and the electrostatic chuck plate may be fixed to each other by a mechanical fixing measure such as screw coupling or bonded to each other with an adhesive. The base substrate 130 and the electrostatic chuck plate 110 may be separately manufactured and bonded to each other, or in some cases, the structure of the electrostatic chuck plate may be directly fabricated on the top surface of the base substrate 130.

The plate 110 and the base substrate 130 may include a predetermined cooling structure configured to uniformly cool a wafer Won the plate 110 by using a cooling gas such as helium (He) in a semiconductor process.

As illustrated, a cooling gas inlet 134 may be provided in the base substrate 130. A flow path extending from the cooling gas inlet 134 passes through the base substrate and is connected to a cooling gas hole 118A in the plate. The cooling gas passing through the flow path formed by the cooling gas inlet 134 and the cooling gas hole 118A is sprayed to a wafer on the top surface of the plate to cool the wafer.

In the present disclosure, in order to more uniformly distribute the cooling gas on the top surface of the plate trenches may be provided on the top surface of the plate as distribution flow paths for guiding the cooling gas to the entire surface of the wafer.

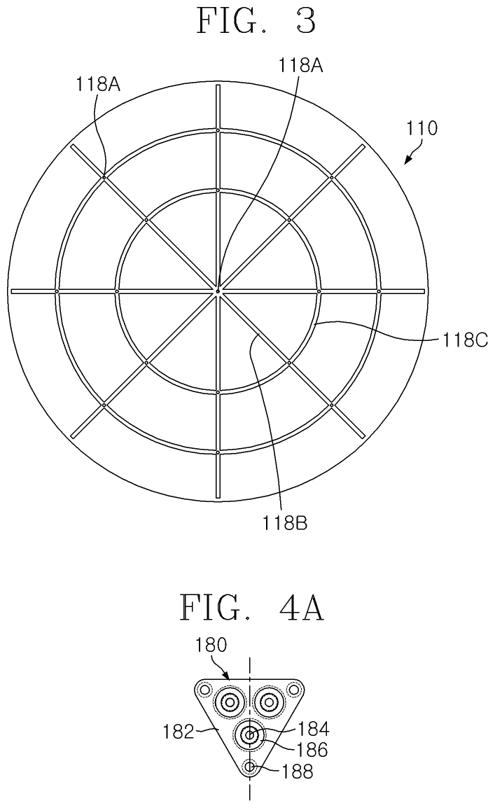

FIG. 3 is a view schematically illustrating a trench structure provided on the top surface of the plate as an embodiment of the present disclosure.

Referring to FIG. 3, the trenches 1186 and 118C on the surface of the plate may radially extend from the position of a central cooling gas hole 118A or branch off from the radial trenches and extend in a circumferential direction. In addition, as illustrated, multiple cooling gas holes 118A may be provided at appropriate positions so that the cooling gas is evenly distributed along the trenches 118B and 118C. For example, the cooling gas holes 118A may be suitably disposed radially or circumferentially at appropriate locations along the trenches. Of course, in order to implement such a multi-hole structure, a flow path that allows the cooling gas holes 118A to communicate with each other may be provided inside the plate. In addition, in the present disclosure, an embossed pattern may be implemented by regularly or irregularly arranging protrusions on the top surface of the plate that supports a wafer for smooth dechucking and particle minimization, and the embossed pattern may allow the cooling gas sprayed from the cooling gas holes 118A to be evenly distributed over the entire wafer.

Referring back to FIG. 2, the plate is provided with chuck electrodes 112. The chuck electrodes 112 may be monopolar or bipolar electrodes. For example, the chuck electrodes 112 may be configured with half-moon-shaped bipolar electrodes that divide the left and right sides of the plate in half, or may be configured with arc-shaped bipolar electrodes including an inner electrode and an outer electrode with reference to the center of the plate. As illustrated, the plate may include connection terminals 70 and leads 72 electrically connecting the chuck electrodes 112 to an external power source.

In the present disclosure, a shaft 170 is provided at the lower end of the base substrate. The shaft 170 supports the base substrate. At the same time, the lower portion of the shaft 170 is assembled with a semiconductor processing apparatus and vacuum-sealed to maintain the connection terminals 70, the leads 72, and a connector assembly 180 at atmospheric pressure. Preferably, the shaft is designed in a tube shape to transfer heat generated from the plate 110 and the base substrate 130 to the apparatus or to allow heat generated in the semiconductor processing apparatus not to be well transferred to the plate 110 and the base substrate 130. To this end, the shaft may be made of a metal having excellent mechanical strength usable in a vacuum environment, such as aluminum, an aluminum alloy, nickel, a nickel alloy, or stainless steel. Unlike this, the shaft may also be implemented with a ceramic material for minimizing heat loss. In addition, the surface of the shaft may be coated with a material having resistance to plasma or halogen-containing gas or anodized.

On the other hand, smooth vacuum sealing inside the base substrate may be implemented by an O-ling 178 sealing manner between the shaft 170 and the base substrate 130.

In the present disclosure, the connector assembly 180 is provided inside the shaft 170. The connector assembly is in airtight contact with the bottom surface of the base substrate 130 by an appropriate airtight element.

The connector assembly includes a flange 182 that is in contact with the base substrate and multiple pipes 82 and 84 connected to the flange to introduce fluid.

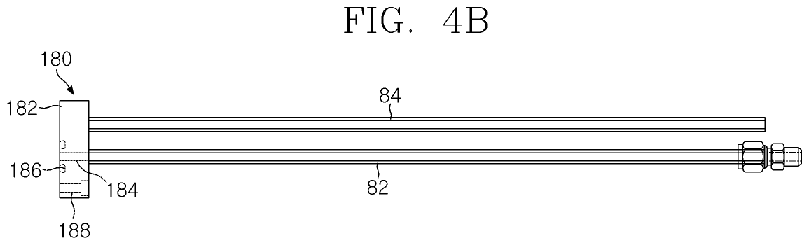

FIG. 4A is a front view of a connector assembly according to an embodiment of the present disclosure, and FIG. 4B is a cross-sectional view of FIG. 4A.

Referring to the drawings, multiple through holes 184 penetrating the top and bottom of the flange 182 are formed. The through holes 184 are connected to multiple pipes 82 and 84, respectively, and communicate with the cooling water inlet 132B and the cooling gas inlet 134 of the base substrate to serve as flow paths for a flow of cooling water or cooling gas introduced thereinto.

In addition, a ring-shaped groove 186 provided along the circumference of the through hole may be included in a contact surface of the flange 182 with the base substrate. An airtight member, such as an O-ring, is mounted in the ring-shaped groove 186 to prevent leakage of cooling gas or cooling medium from the contact surface with the base substrate.

Meanwhile, as illustrated, the flange 182 of the above-described connector assembly 180 may be fixed to the base substrate 130 in an appropriate manner. As illustrated in FIG. 4B, the flange may be screwed to the base substrate 130 through the screw groove provided in the flange.

On the other hand, in the present disclosure, as illustrated, the shaft 170 preferably has a tubular or cylindrical structure with an empty inside. In addition, the shaft 170 may include a narrow shaft portion 172 having a small diameter, an expanded shaft portion 174 having a diameter greater than that of the narrow shaft portion 172, and a shaft flange 176 which is in contact with the base substrate. By adopting this structure, it is possible to mount the connector assembly structure therein while suppressing heat loss of the cooling fluid by minimizing the diameter of the shaft.

In the present disclosure, the cooling structure including the connector assembly 180 and the shaft is preferably aligned with the central axis of the plate. Specifically, the connector assembly 180 is preferably disposed within an area having a predetermined radius (e.g., an area having a radius corresponding to ½, ⅓, or ¼ of the radius of the plate) from the center of the plate.

A cooling operation for the electrostatic chuck performed by the above-mentioned connector assembly by using cooling water and cooling gas is as follows.

The cooling water pipe 84 of the connector assembly 180 is airtightly connected to the cooling water inlet 132B of the base substrate 130 to supply cooling water to the cooling water channel 132A in the base substrate, and the supplied cooling water is discharged to the outside and circulated by passing through the cooling water channel and then passing through the cooling water pipe 84 again. Meanwhile, the cooling gas supplied by the cooling gas pipe 82 passes through the cooling gas inlet 134 of the base substrate 130 and is sprayed through the cooling gas holes 118A in the plate 110. The sprayed cooling gas may be evenly distributed over the entire wafer by the trenches and/or embossed structure to cool the wafer.

As described above, the present disclosure simplifies the cooling structure by integrating the cooling mechanism inside the shaft. By adopting such a centralized cooling structure, it is possible to efficiently cool the base substrate and the plate without loss of cooling efficiency.

In this case, the shaft itself is preferably minimized in size (outer diameter and inner diameter) to minimize heat loss to the outside of a process apparatus or heat supply from the process apparatus and to perform a role of thermally isolating the base substrate.

In addition, the present disclosure uses the connector assembly in incorporating the cooling mechanism to the shaft, thereby performing centralized supply of multiple cooling fluids flowing in multiple flow paths while making it possible to maintain airtightness between the fluids.

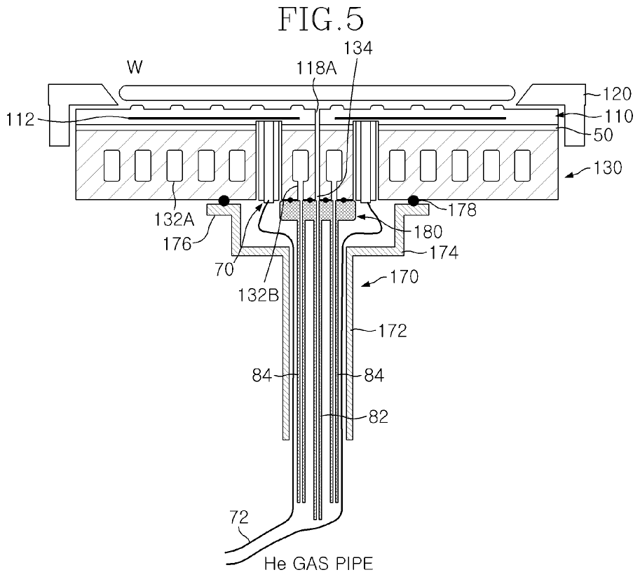

FIG. 5 is a schematic cross-sectional view of an electrostatic chuck according to another embodiment of the present disclosure.

Unlike the electrostatic chuck of FIG. 2, the electrostatic chuck of FIG. 5 includes a guide ring along the outer circumference of the plate 110.

The guide ring includes a ring portion surrounding the side surface of the plate and an extension portion extending from the ring portion to the top surface of the plate. The guide ring having the above-mentioned structure minimizes etching of the edge portion of the insulating plate. In addition, the guide ring is capable of protecting a bonding layer exposed on the side surface between the plate and the base substrate from etching.

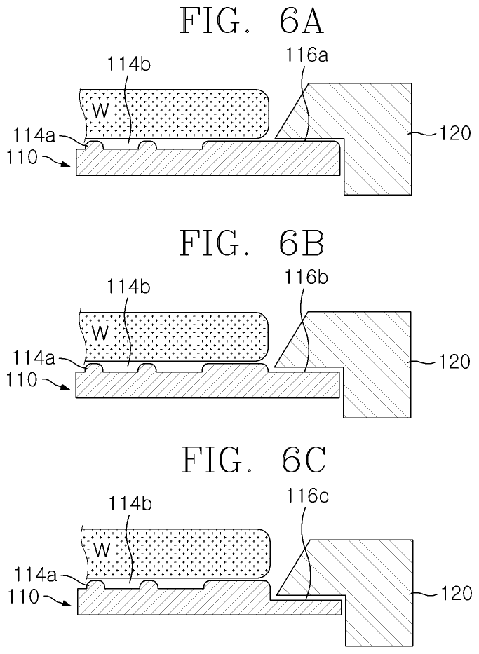

FIGS. 6A to 6C are views illustrating an example of application of a guide ring according to characteristics of a plate.

As illustrated in FIGS. 6A to 6C, the guide ring may be appropriately arranged depending on the shape and thickness of the plate edge 116a, 116b, or 116c.

In the present disclosure, the guide ring fixes the position of a wafer and prevents the wafer seated on the electrostatic chuck movement from moving (e.g., sliding) when lift pins are lowered. In addition, the guide ring ensures a smooth and efficient process by allowing reactive gases sprayed through an upper showerhead or a gas nozzle in a process apparatus to properly react on the surface of a wafer to be processed during a gas residence time (reaction time). Furthermore, the guide ring is able to protect the ceramic of the electrostatic chuck ceramic from etching or contamination during an etch or vapor deposition process. In addition, the guide ring is able to prevent the bonding layer between the base substrate and the ceramic plate from being directly exposed to plasma or process gas chemicals, thereby increasing the life span of the electrostatic chuck.

FIG. 6A illustrates a guide ring fastening structure in which a plate edge 116a is disposed on the same plane as the top surface of the plate 110 and a guide ring fastening portion is located on the plate edge 116a. In this structure, since it is possible to fabricate the edge of the ceramic plate at which the electrostatic chuck is fastened to relatively thick, the mechanical strength of the fastening portion is excellent. In contrast, there are disadvantages in that the exposed portion of a ceramic base material is easily etched and that the edge portion of the wafer may be contaminated when particles are generated due to the etching of a silicon wafer. Meanwhile, FIG. 6B illustrates a guide ring fastening structure in which a plate edge 116b is disposed on the same plane as the lower ends of protrusions 114a of the plate 110 and a guide ring fastening portion is located on the plate edge 116b. This structure has an advantage of minimizing etching of ceramic at the edge portion of a wafer contact surface. FIG. 6C illustrates an example in which a plate edge 116c is stepped downward below the lower end surfaces of the protrusions 114a. Compared to those of FIGS. 6A and 6B, this structure is capable of facilitating close fastening of the guide ring and capable of minimizing etching of the ceramic base material and a change in roughness at the edge of the electrostatic chuck since the exposed ceramic is not the electrostatic attractive surface. In addition, this structure has an advantage of minimizing heat loss of a wafer edge due to fastening of the guide ring.

In the foregoing, specific details such as specific components of the present disclosure have been described with limited embodiments and drawings. However, the description is provided merely to help a more general understanding of the present disclosure but is not intended to limit the present disclosure to the above-described embodiments. A person ordinarily skilled in the art to which the present disclosure pertains may make various modifications and variations without departing from the essential characteristics of the present disclosure. Therefore, the spirit of the present disclosure is not limited to the described embodiments, and not only the appended claims, but also all technical ideas equivalent to the claims or having modifications equivalent to the claims are to be interpreted as being included in the scope of the present disclosure.

What is claimed is:

1. An electrostatic chuck comprising:
a base substrate comprising a cooling water channel;
a plate configured to support a wafer on the base substrate and comprising a cooling gas hole configured to supply a cooling gas to the wafer; and
a shaft abutting the base substrate along a circumference of a central portion of the base substrate comprising a cooling water inlet and a cooling gas inlet,
wherein the base substrate comprises the cooling water inlet and the cooling gas inlet in a center thereof,
wherein the plate is in communication with the cooling gas inlet of the base substrate and comprises the cooling gas hole configured to spray a cooling gas to the wafer.

2. The electrostatic chuck of claim 1, wherein the shaft comprises a connector assembly configured to introduce a fluid into the cooling water inlet and the cooling gas inlet.

3. The electrostatic chuck of claim 2, wherein the connector assembly comprises:
a flange that is in contact with the base substrate and comprises multiple through holes therein; and
multiple pipes connected to the multiple through holes of the flange to introduce the fluid.

4. The electrostatic chuck of claim 3, wherein the flange is in airtight contact with the base substrate.

5. The electrostatic chuck of claim 4, wherein the multiple through holes of the flange communicate with the cooling water inlet or the cooling gas inlet of the base substrate.

6. The electrostatic chuck of claim 5, further comprising:
a ring-shaped groove provided for airtight sealing along a periphery of the through holes.

7. The electrostatic chuck of claim 1, wherein the plate comprises a bipolar chuck electrode.

8. The electrostatic chuck of claim 1, wherein the plate comprises a cooling flow path formed by a trench radially extending on a top surface thereof.

9. The electrostatic chuck of claim 8, wherein the cooling flow path of the plate further comprises multiple cooling gas holes.

10. The electrostatic chuck of claim 1, wherein the plate comprises an embossed pattern on a surface thereof that comes into contact with a wafer.

11. The electrostatic chuck of claim 1, further comprising:
a guide ring,
wherein the guide ring comprises:
a ring portion surrounding a side surface of the plate; and
an extension portion extending from the ring portion to a top surface of the plate.

12. The electrostatic chuck of claim 1, wherein the plate further comprises a built-in heater.

13. The electrostatic chuck of claim 12, wherein the built-in heater is a concentric multi-zone heater.
